(19) United States
(12) Patent Application Publication
(10) Pub. No.: US 2009/0243093 A1
(43) Pub. Date: Oct. 1, 2009

(54) CONTACT STRUCTURE AND CONNECTING STRUCTURE

(75) Inventor: Shyh-Ming Chang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignees: TAIWAN TFT LCD ASSOCIATION, Hsinchu (TW); CHUNGHWA PICTURE TUBES, LTD., Taipei (TW); AU OPTRONICS CORPORATION, Hsinchu (TW); HANNSTAR DISPLAY CORPORATION, Taipei City (TW); CHI MEI OPTOELECTRONICS CORPORATION, Tainan County (TW); INDUSTRIAL TECHNOLOGY RESEARCH INSTITUTE, Hsinchu (TW)

(21) Appl. No.: 12/366,629

(22) Filed: Feb. 5, 2009

(30) Foreign Application Priority Data
Mar. 27, 2008 (TW) 97111019

(51) Int. Cl. H01L 23/48

(52) U.S. Cl. 257/737; 257/690; 257/686; 257/E23.021

(57) ABSTRACT

A contact structure disposed on a substrate is provided. The contact structure includes at least one pad, at least one polymer bump and at least one conductive layer. The pad is disposed on the substrate and the polymer bump is disposed on the substrate. The polymer bump has a curved surface having a plurality of concave-convex structures. The polymer bump is covered by the conductive layer and the conductive layer is electrically connected with the pad.

### CROSS-REFERENCE TO RELATED APPLICATION

This application claims the priority benefit of Taiwan application serial no. 97111019, filed Mar. 27, 2008. The entirety of the above-mentioned patent application is hereby incorporated by reference herein and made a part of specification.

### BACKGROUND OF THE INVENTION

1. Field of the Invention

The present invention relates to a contact structure and a connecting structure, and particularly relates to a contact structure and a connecting structure with better electric reliability.

2. Description of Related Art

Along with the progress of technology, all kinds of electronic devices are developed in the direction of miniaturization and multiple functions. To increase the signals transmitted and received by the chips in electronic devices, the density of the contacts electrically connecting the chip with the circuit board is increased.

According to a conventional technique, a common method for electrically connecting the chip with a glass substrate is to dispose an anisotropic conductive film (ACF) between the contacts of the chip and a conductive structure of the glass substrate. The contacts of the chip and the conductive structure of the glass substrate both face the anisotropic conductive film. Then, the contacts, the anisotropic conductive film, and the conductive structure of the glass substrate are compressed so that the conductive particles in the anisotropic conductive film can electrically connect the contacts with corresponding conductive structures on the glass substrate.

However, the interspaces between the contacts of the chip and the interspaces between the conductive structures of the glass substrate are both reduced as the densities of the contacts and the conductive structures increases. As a consequence, the contacts of the chip might electrically connect to the contacts or the conductive structures nearby through the anisotropic conductive film, and cause short circuit or electric leakage.

Hence, an idea, which uses a column polymer bump covered by a metal layer as the contact structure of the chip, is proposed. A method for electrically connecting the contacts of the chip with the conductive structures of the glass substrate is to dispose a non-conductive adhesion layer between the chip and the conductive structures of the glass substrate. Then, the chip is compressed onto the glass substrate so that the column polymer bump can pass through the non-conductive adhesion layer to contact and electrically connect with the conductive structures of the glass substrate.

However, stress concentration easily occurs during this process and results in the breaking of the metal layer. Consequently, the electric reliability thereof is influenced.

### SUMMARY OF THE INVENTION

The present invention provides a contact structure, which prevents stress concentration during the connection of a polymer bump and another substrate.

The present invention further provides a contact structure, which allows a polymer bump to easily pass through a bonding material during the connection of the polymer bump and another substrate.

The present invention further provides a connecting structure, which has better electric reliability.

To specify the content of the present invention, a contact structure disposed on a substrate is described in detail as follows. The contact structure comprises at least a pad, at least a polymer bump, and at least a conductive layer. Herein, the pad is disposed on the substrate, and the polymer bump is disposed on the substrate. The polymer bump has a curved surface, which comprises a plurality of concave-convex structures. The conductive layer covers the polymer bump and is electrically connected with the pad.

To specify the content of the present invention, a contact structure disposed on a substrate is described in detail as follows. The contact structure comprises at least a pad, at least a polymer bump, and at least a conductive layer. The pad is disposed on the substrate, and the polymer bump is disposed on the substrate. The polymer bump has a top flat surface and curved surfaces having concave-convex structures thereon at two sides of the top flat surface. The conductive layer covers the polymer bump and is electrically connected with the pad.

To specify the content of the present invention, a connecting structure, which comprises a first substrate, a second substrate, and a bonding material, is described in detail as follows. The first substrate comprises at least a pad, at least a polymer bump, and at least a conductive layer. The polymer bump is disposed to be corresponding to the pad, and the polymer bump has a curved surface comprising a plurality of concave-convex structures. The conductive layer covers the polymer bump and is electrically connected with the pad. The second substrate comprises at least a conductive structure, wherein the conductive layer of the first substrate is electrically connected with the conductive structure. The bonding material is disposed between the first substrate and the second substrate. Further, a portion of the conductive layer and the polymer bump pass through the bonding material to contact the conductive structure.

To specify the content of the present invention, a connecting structure, which comprises a first substrate, a second substrate, and a bonding material, is described in detail as follows. The first substrate comprises at least a pad, at least a polymer bump, and at least a conductive layer. The polymer bump is disposed to be corresponding to the pad. The polymer bump has a top flat surface and curved surfaces having concave-convex structures thereon at two sides of the top flat surface. The conductive layer covers the polymer bump and is electrically connected with the pad. The second substrate comprises at least a conductive structure, wherein the conductive layer of the first substrate is electrically connected with the conductive structure. The bonding material is disposed between the first substrate and the second substrate. Further, a portion of the conductive layer and the polymer bump pass through the bonding material to contact the conductive structure.

In view of the above, the polymer bump of the contact structure and the connecting structure according to the present invention has a curved surface, which comprises a plurality of concave-convex structures. Hence, the polymer bump can prevent stress concentration which easily results in the breaking of a metal layer on a conventional polymer bump when contacting another substrate. Furthermore, when the polymer bump contacts the second substrate, the concave-convex structures help the polymer bump pass through the bonding material to contact the conductive structure of the second substrate.

To make the above and other objectives, features, and advantages of the present invention more comprehensible, preferable embodiments accompanied with figures are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a contact structure according to an embodiment of the present invention.

FIGS. 2˜13 are schematic cross-sectional views illustrating the variety of the contact structure in FIG. 1.

FIG. 14A is a schematic top view of a contact structure according to an embodiment of the present invention.

FIG. 14B is a schematic cross-sectional view illustrating the contact structure along the line I-I′ in FIG. 14A.

FIG. 14C is a schematic cross-sectional view illustrating the contact structure along the line II-II′ in FIG. 14A.

FIG. 15A is a schematic top view of a contact structure according to another embodiment of the present invention.

FIG. 15B is a schematic cross-sectional view illustrating the contact structure along the line I-I′ in FIG. 15A.

FIG. 15C is a schematic cross-sectional view illustrating the contact structure along the line II-II′ in FIG. 15A.

FIG. 16 is a schematic cross-sectional view of a contact structure according to an embodiment of the present invention.

FIGS. 17˜28 are schematic cross-sectional views illustrating the variety of the contact structure in FIG. 16.

FIG. 29A is a schematic top view of a contact structure according to an embodiment of the present invention.

FIG. 29B is a schematic cross-sectional view illustrating the contact structure along the line I-I′ in FIG. 29A.

FIG. 29C is a schematic cross-sectional view illustrating the contact structure along the line II-II′ in FIG. 29A.

FIG. 30A is a schematic top view of a contact structure according to another embodiment of the present invention.

FIG. 30B is a schematic cross-sectional view illustrating the contact structure along the line I-I′ in FIG. 30A.

FIG. 30C is a schematic cross-sectional view illustrating the contact structure along the line II-II′ in FIG. 30A.

FIG. 31 is a schematic cross-sectional view of a contact structure according to another embodiment of the present invention.

FIG. 32 is a schematic cross-sectional view illustrating a connecting structure before connection according to an embodiment of the present invention.

FIGS. 33 and 34 are schematic cross-sectional views of a connecting structure according to an embodiment of the present invention.

FIG. 35 is a schematic cross-sectional view illustrating a connecting structure before connection according to an embodiment of the present invention.

FIGS. 36 and 37 are schematic cross-sectional views of a connecting structure according to an embodiment of the present invention.

FIGS. 38A and 38B are schematic cross-sectional views of a contact structure according to another embodiment of the present invention.

FIGS. 39A˜39E are schematic cross-sectional views illustrating a method for forming a contact structure according to an embodiment of the present invention.

### DESCRIPTION OF EMBODIMENTS

### First Embodiment

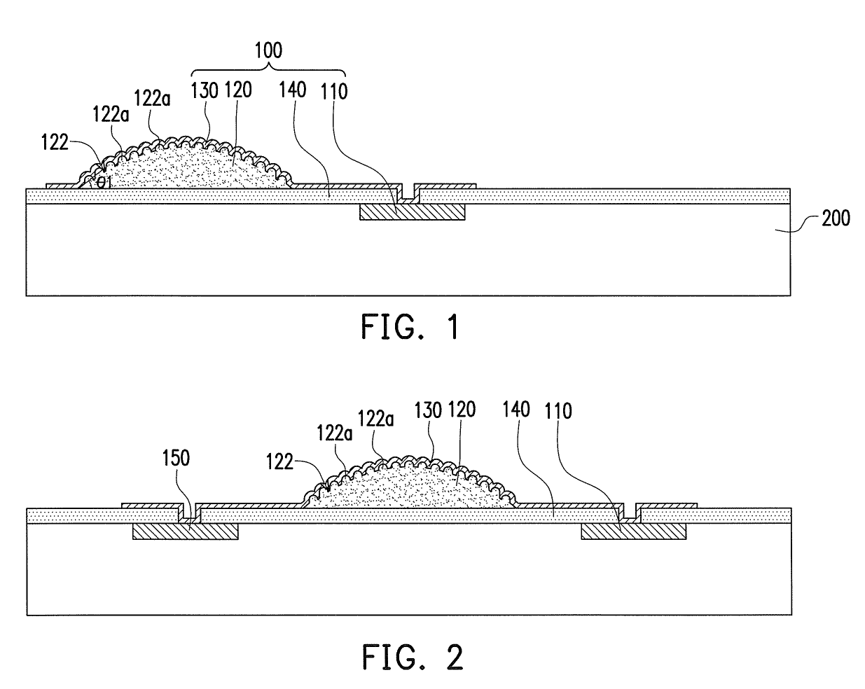

FIG. 1 is a schematic cross-sectional view of a contact structure according to an embodiment of the present invention. Referring to FIG. 1, in this embodiment, a contact structure 100 is disposed on a substrate 200. The contact structure 100 comprises a pad 110, a polymer bump 120, and a conductive layer 130. Herein, the pad 110 is disposed on the substrate 200, and the polymer bump 120 is disposed on the substrate 200. The polymer bump 120 has a curved surface 122, which comprises a plurality of concave-convex structures 122a. The conductive layer 130 covers the polymer bump 120 and is electrically connected with the pad 110. It is noted that, in this embodiment, the curved surface 122 protrudes in a direction away from the substrate 200, and a first contact angle θ1 between the curved surface 122 and the substrate 200 is, for example, larger than 0 and smaller than or equal to 80 degrees.

In view of the above, the polymer bump 120 of the present invention has the curved surface 122, which comprises a plurality of concave-convex structures 122a. The curved surface 122 of the polymer bump 120 prevents stress concentration which occurs when the polymer bump 120 contacts another substrate. Hence, the polymer bump 120 is capable of preventing stress concentration which easily results in the breaking of a metal layer on a conventional polymer bump when contacting another substrate. In addition, when a bonding material is disposed between the substrate 200 and another substrate, the concave-convex structures 122a help the polymer bump 120 to pass through the bonding material to contact another substrate.

To conclude, the spirit of the present invention lies in that the polymer bump has the curved surface which comprises a plurality of concave-convex structures. Thereby, the problem of stress concentration which occurs when the polymer bump contacts another substrate can be solved. Further, the concave-convex structures help the polymer bump to pass through the bonding material disposed between the substrate and another substrate, so as to contact another substrate. Anybody skilled in the art may make some modifications or alterations without departing from the spirit and scope of the present invention.

Referring to FIG. 1, the contact structure 100 further comprises a passivation layer 140, which is disposed on the substrate 200 and exposes the pad 110. In the first embodiment, the polymer bump 120 may be formed by using a gray level photomask. To be more specific, a photosensitive material may be used to form the polymer bump. Then, the specially designed gray level photomask is used to expose the photosensitive material. After development, the polymer bump 120 which has the curved surface 122 comprising the concave-convex structures 122a is formed. Thereafter, a deposition process, a sputtering process, or an electroplating process is used to form a conductive layer 130, which compliantly covers the surface of the polymer bump 120. Hence, the conductive layer 130 also has a concave-convex surface.

In the present invention, variations may be made between the polymer bump 120 and the conductive layer 130. The variations of the contact structure 100 in FIG. 1 are described in detail as follows.

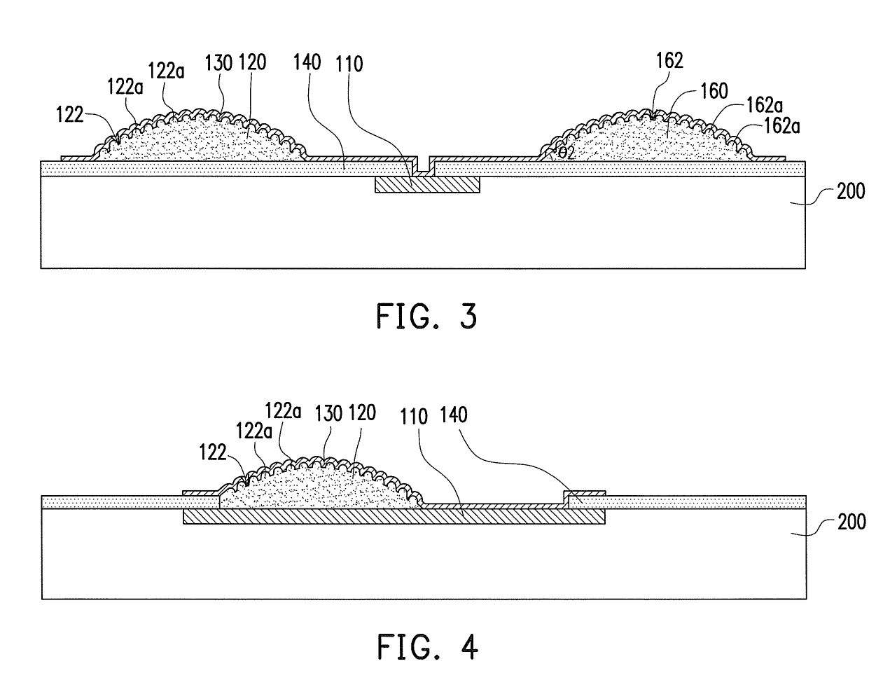

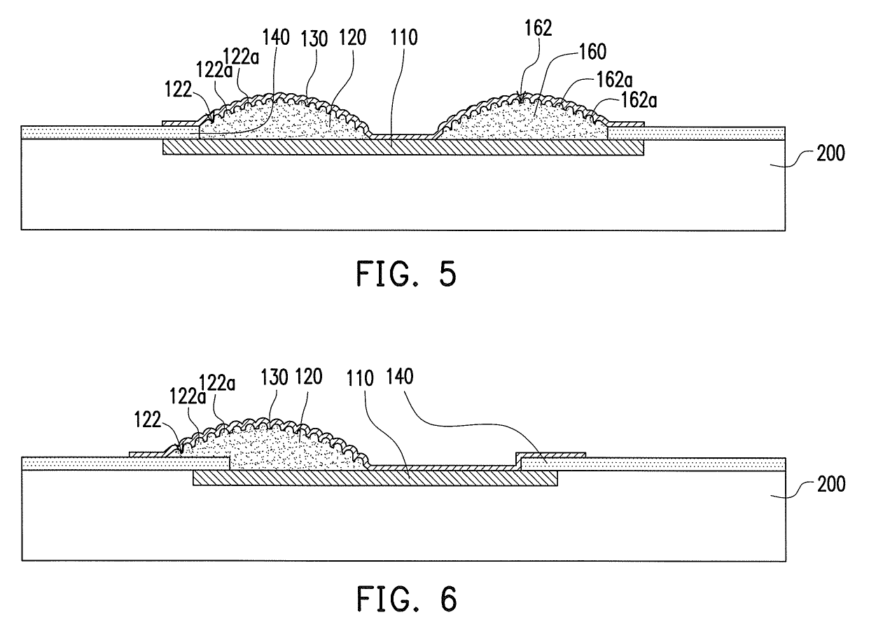

In addition to the polymer bump 120, the pad 110, and the conductive layer 130 as shown in FIG. 1, a contact structure in FIG. 2 further comprises a pad 150 disposed on the substrate 200. Particularly, the polymer bump 120 is arranged between the pads 110 and 150. The conductive layer 130 covering the polymer bump 120 extends to the surfaces of the pads 110 and 150 to electrically connect with the pads 110 and 150.

In addition to the polymer bump 120, the pad 110, and the conductive layer 130 as shown in FIG. 1, a contact structure in FIG. 3 further comprises a polymer bump 160 disposed on the substrate 200. The pad 110 is arranged between the polymer bumps 160 and 120, and the conductive layer 130 covers the polymer bump 160. Moreover, the polymer bump 160 has a curved surface 162, which comprises a plurality of concave-convex structures 162a. It is noted that, in this embodiment, the curved surface 162 protrudes in a direction away from the substrate 200, and a second contact angle θ2 between the curved surface 162 and the substrate 200 is, for example, larger than 0 and smaller than or equal to 80 degrees.

The polymer bump as shown in FIGS. 1˜3 does not cover the pad 110. However, in the present invention, the polymer bump may also be disposed on the pad 110. As shown in FIG. 4, the polymer bump 120 is disposed on a surface of the pad 110 and exposes a portion of the pad 110, so that the conductive layer 130 covering the polymer bump 120 can be electrically connected with the exposed pad 110. Similarly, as shown in FIG. 5, the polymer bumps 120 and 160 are both disposed on the pad 110 and expose a portion of the pad 110. Hence, the conductive layer 130 covering the polymer bumps 120 and 160 is able to electrically connect with the exposed pad 110.

The polymer bump may be disposed on the pad 110 or not on the pad 110. In addition, a portion of the polymer bump may be disposed on the pad 110 while another portion of the polymer bump is disposed on the substrate 200. As shown in FIG. 6, the polymer bump 120 simultaneously traverses the pad 110 and the substrate 200. In other words, a portion of the polymer bump 120 is disposed on the surface of the pad 110 and exposes a portion of the pad 110, while another portion of the polymer bump 120 is disposed on the substrate 200 or the passivation layer 140. Thereby, the conductive layer 130 covering the polymer bump 120 is able to electrically connect with the exposed pad 110. Similarly, as shown in FIG. 7, a portion of the polymer bumps 120 and 160 is disposed on the pad 110 and exposes a portion of the pad 110, while another portion of the polymer bumps 120 and 160 is disposed on the substrate 200 or the passivation layer 140. Thereby, the conductive layer 130 covering the polymer bumps 120 and 160 is able to electrically connect with the exposed pad 110.

The embodiments in FIGS. 1˜7 all illustrate that the conductive layer 130 wholly covers the polymer bumps. In fact, the conductive layer 130 of the present invention may partially cover the polymer bumps, as described in the following paragraphs.

The embodiments in FIGS. 8˜13 are similar to the embodiments in FIGS. 1˜7. The difference lies in that the conductive layer 130 in FIGS. 8˜13 partially covers the polymer bump 120 or partially covers the polymer bumps 120 and 160.

In addition, the polymer bumps in the above embodiments may be block structures or strip structures.

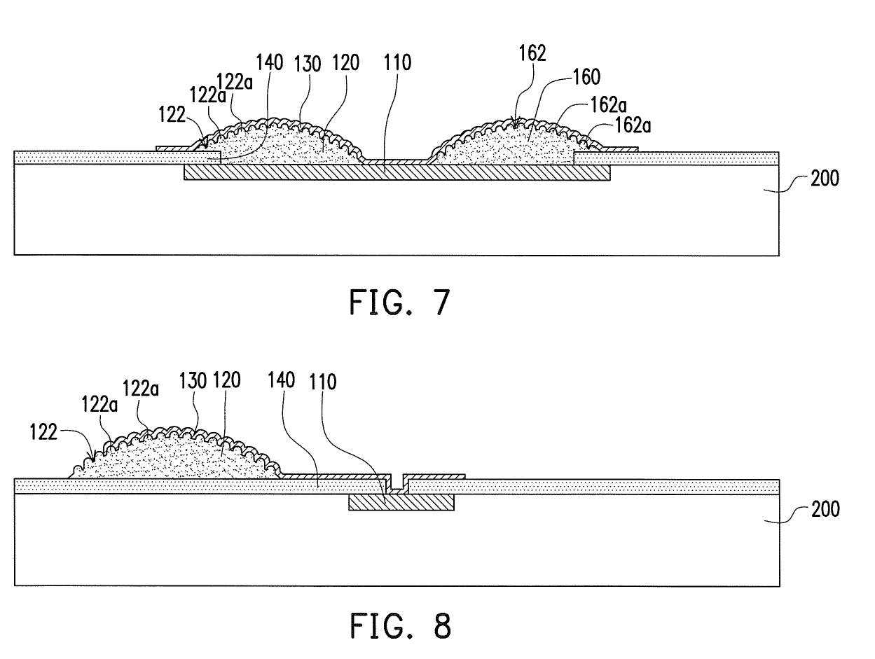

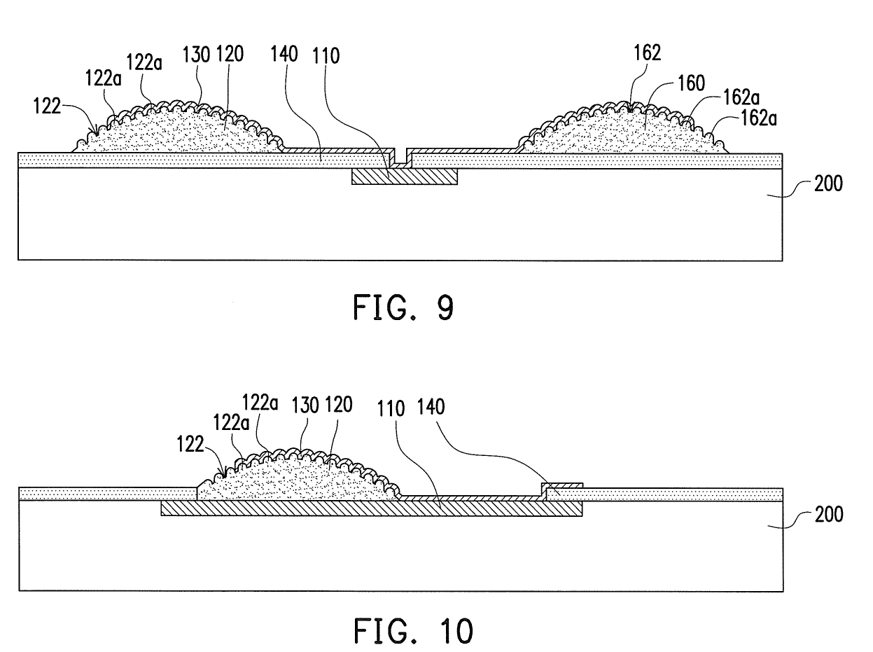

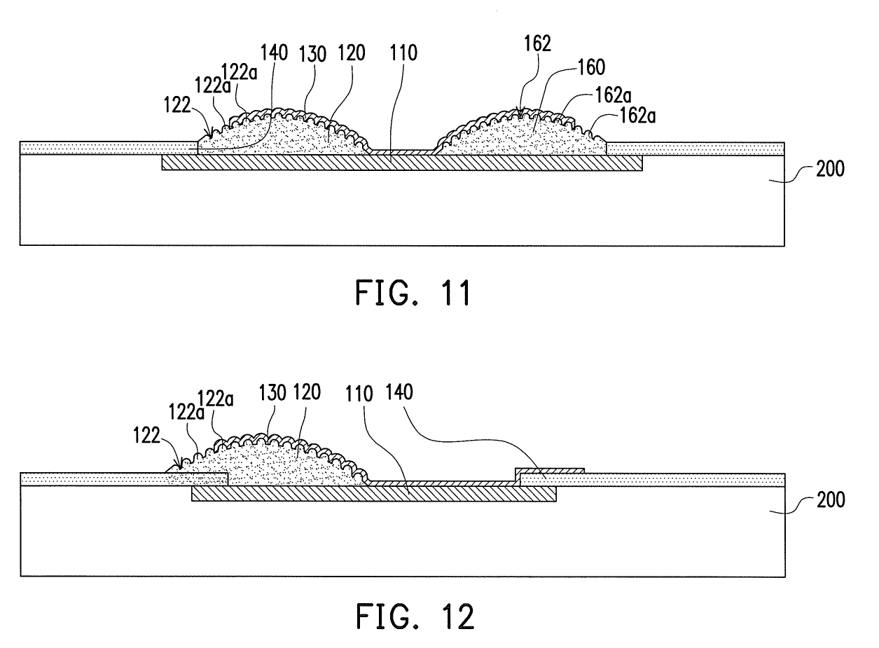

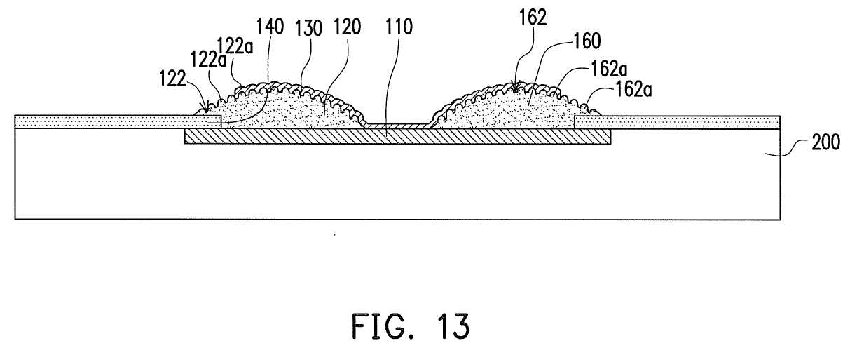

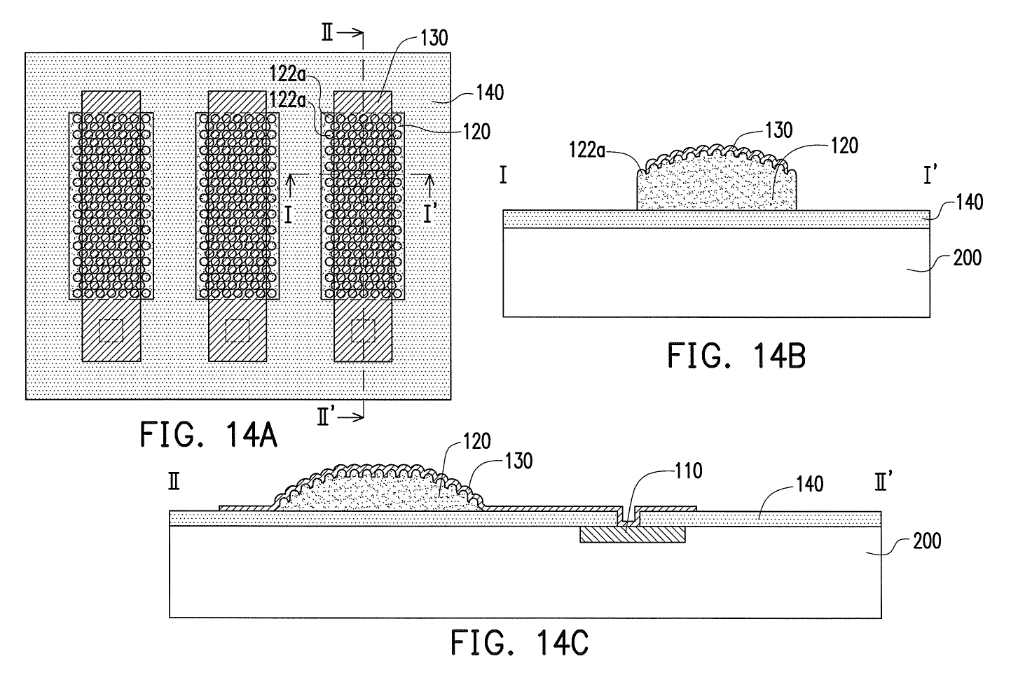

FIGS. 14A˜14C illustrate an embodiment in which the polymer bumps are block structures. More particularly, the illustration of FIGS. 14A˜14C is based on the arrangement of the polymer bump in FIG. 1. Although the present specification does not specifically illustrate the block structures of the polymer bumps in the embodiments of FIGS. 2˜13, persons skilled in the art should have such an understanding based on the illustration of FIGS. 14A˜14C.

FIG. 14A is a schematic top view illustrating a contact structure according to an embodiment of the present invention. FIG. 14B is a schematic cross-sectional view illustrating the contact structure along the line I-I′ in FIG. 14A and FIG. 14C is a schematic cross-sectional view illustrating the contact structure along the line II-II′ in FIG. 14A. Referring to FIGS. 14A˜14C, the polymer bump 120 is a block structure, and the surface of the polymer bump 120 comprises the concave-convex structures 122a. Because the polymer bump 120 is a block structure, each polymer bump 120 is covered by a conductive layer 130 correspondingly.

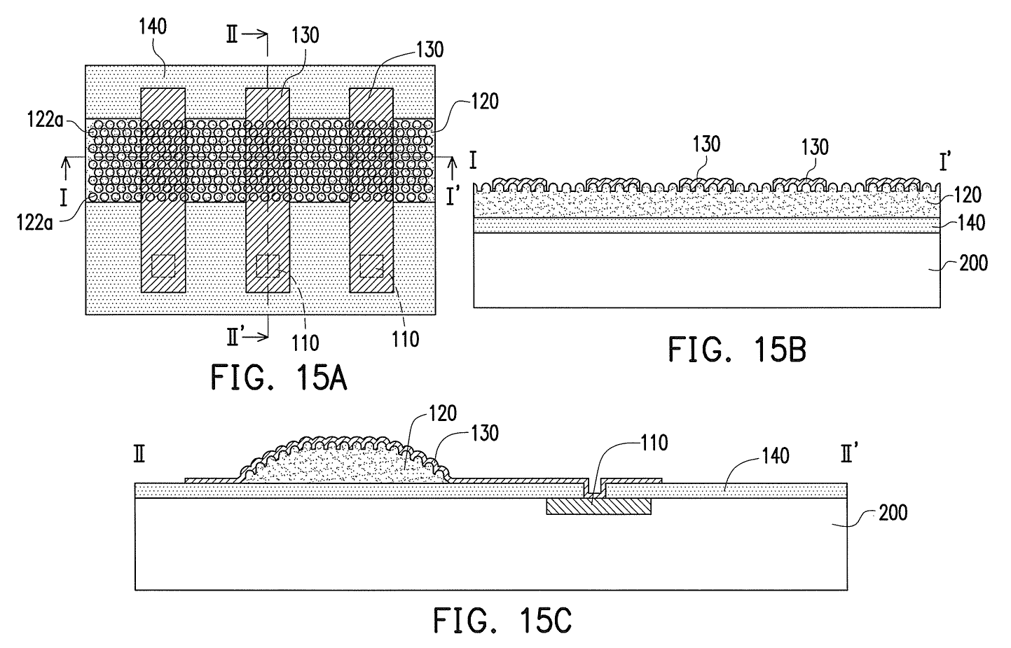

FIGS. 15A˜15C illustrate an embodiment in which the polymer bumps are strip structures. More particularly, the illustration of FIGS. 15A˜15C is based on the arrangement of the polymer bump in FIG. 1. Although the present specification does not specifically illustrate the strip structures of the polymer bumps in the embodiments of FIGS. 2˜13, persons skilled in the art should have such an understanding based on the illustration of FIGS. 15A˜15C.

FIG. 15A is a schematic top view illustrating a contact structure according to an embodiment of the present invention. FIG. 15B is a schematic cross-sectional view illustrating the contact structure along the line I-I′ in FIG. 15A and FIG. 15C is a schematic cross-sectional view illustrating the contact structure along the line II-II′ in FIG. 15A. Referring to FIGS. 15A˜15C, when the polymer bump 120 is a strip structure, one polymer bump 120 is covered by a plurality of conductive layers 130, wherein each of the conductive layers 130 is electrically connected with one corresponding pad 110. Further, in other embodiments, one polymer bump may be covered by a plurality of conductive layers electrically connected with one pad.

### Second Embodiment

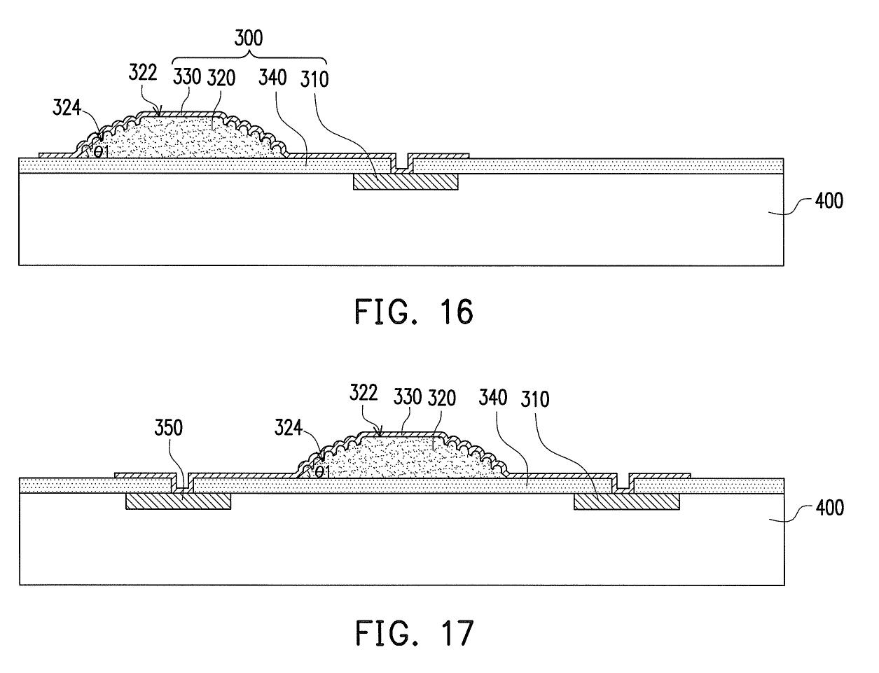

FIG. 16 is a schematic cross-sectional view of a contact structure according to the second embodiment of the present invention. Referring to FIG. 16, in this embodiment, a contact structure 300 is disposed on a substrate 400. The contact structure 300 comprises a pad 310, a polymer bump 320, and a conductive layer 330. Herein, the pad 310 is disposed on the substrate 400, and the polymer bump 320 is disposed on the substrate 400. The polymer bump 320 has a top flat surface 322 and curved surfaces 324 having concave-convex structures thereon at two sides of the top flat surface 322. In this embodiment, the top flat surface 322 is a smooth structure. The conductive layer 330 covers the polymer bump 320 and is electrically connected with the pad 310. It is noted that, in this embodiment, the curved surfaces 324 having concave-convex structures thereon protrude in a direction away from the substrate 400, and a first contact angle θ1 between the curved surfaces 324 having concave-convex structures thereon and the substrate 400 is, for example, larger than 0 and smaller than or equal to 80 degrees.

In view of the above, the polymer bump 320 of the present invention comprises curved surfaces 324 having concave-convex structures thereon. The curved surfaces 324 having concave-convex structures thereon of the polymer bump 320 do not cause stress concentration when the polymer bump 320 contacts another substrate. Hence, the polymer bump 320 is capable of preventing stress concentration which easily results in the breaking of a metal layer on a conventional polymer bump when contacting another substrate In addition, the top flat surface 322 increases an area for contacting another substrate.

Referring to FIG. 16, the contact structure 300 in this embodiment further comprises a passivation layer 340, which is disposed on the substrate 400 and exposes the pad 310. In an embodiment, the polymer bump 320 may be formed by using a gray level photomask. To be more specific, a photosensitive material may be used to form the polymer bump 320. Then, the specially designed gray level photomask is used to expose the photosensitive material. After development, the polymer bump 320 which has the top flat surface 322 and the curved surfaces 324 having concave-convex structures thereon is formed. Thereafter, a deposition process is used to form the conductive layer 330, which compliantly covers the surface structure of the polymer bump 320. Accordingly, the conductive layer 330 covering the top flat surface 322 also has a top flat surface, and the conductive layer 330 covering the curved surfaces 324 having concave-convex structures thereon also has curved concave-convex surfaces.

In the present invention, variations may be made between the polymer bump 320 and the conductive layer 330. The variations of the contact structure 300 in FIG. 16 are described in detail as follows.

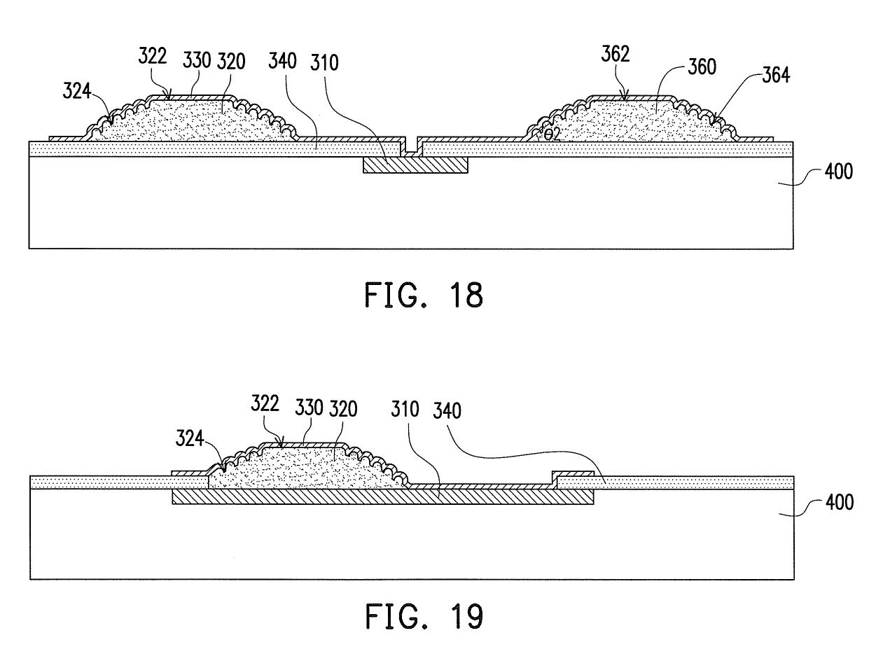

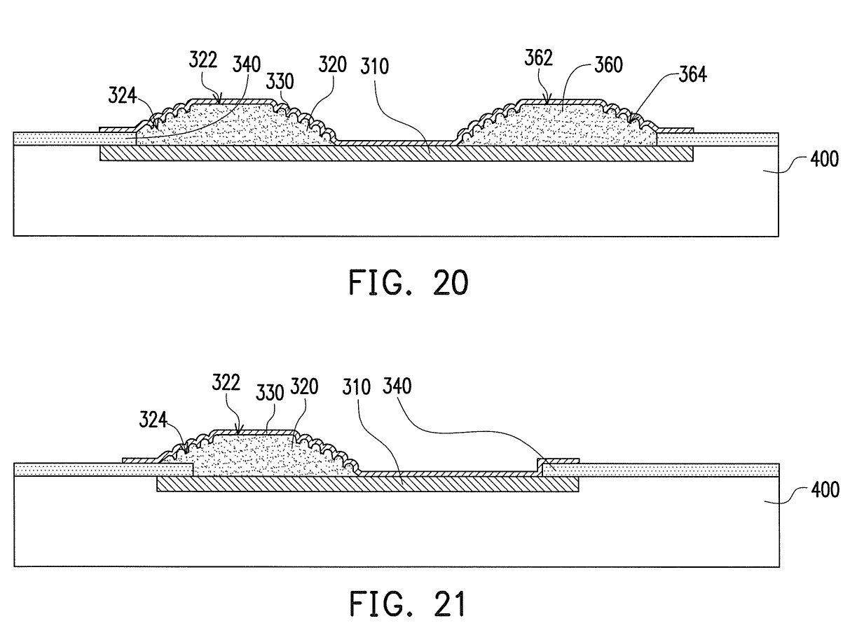

In addition to the polymer bump 320, the pad 310, and the conductive layer 330 as shown in FIG. 16, a contact structure in FIG. 17 further comprises a pad 350 disposed on the substrate 400. Particularly, the polymer bump 320 is arranged between the pads 310 and 350, and the conductive layer 330 covering the polymer bump 320 extends to the surfaces of the pads 310 and 350 to electrically connect with the pads 310 and 350.

In addition to the polymer bump 320, the pad 310, and the conductive layer 330 as shown in FIG. 16, a contact structure in FIG. 18 further comprises a polymer bump 360 disposed on the substrate 400. The pad 310 is arranged between the polymer bumps 360 and 320, and the conductive layer 330 covers the polymer bump 360. Moreover, the polymer bump 360 has a top flat surface 362 and curved surfaces 364 having concave-convex structures thereon at two sides of the top flat surface 362. In this embodiment, the curved surfaces 364 having concave-convex structures thereon protrude in a direction away from the substrate 400, and the second contact angle θ2 between the curved surfaces 364 having concave-convex structures thereon and the substrate 400 is, for example, larger than 0 and smaller than or equal to 80 degrees.

The polymer bumps as shown in FIGS. 16˜18 do not cover the pads. However, in the present invention, the polymer bump 320 may also be disposed on the pad 310. As shown in FIG. 19, the polymer bump 320 is disposed on the surface of the pad 310 and exposes a portion of the pad 310, so that the conductive layer 330 covering the polymer bump 320 can be electrically connected with the exposed pad 310. Similarly, as shown in FIG. 20, the polymer bumps 320 and 360 are both disposed on the pad 310 and expose a portion of the pad 310. Hence, the conductive layer 330 covering the polymer bumps 320 and 360 is able to electrically connect with the exposed pad 310.

The polymer bump 320 may be disposed on the pad 310 or not on the pad 310. In addition, the polymer bump 320 may also be disposed to simultaneously traverse the pad 310 and the substrate 400. In other words, a portion of the polymer bump 320 is disposed on the pad 310, while another portion of the polymer bump 320 is disposed on the substrate 400. As shown in FIG. 21, a portion of the polymer bump 320 is disposed on the surface of the pad 310 and exposes a portion of the pad 310, while another portion of the polymer bump 320 is disposed on the substrate 400 or the passivation layer 340. Thereby, the conductive layer 330 covering the polymer bump 320 is able to electrically connect with the exposed pad 310. Similarly, as shown in FIG. 22, a portion of the polymer bumps 320 and 360 is disposed on the pad 310 and exposes a portion of the pad 310, while another portion of the polymer bumps 320 and 360 is disposed on the substrate 400 or the passivation layer 340. Thereby, the conductive layer 330 covering the polymer bumps 320 and 360 is able to electrically connect with the exposed pad 310.

The embodiments in FIGS. 16˜22 all illustrate that the conductive layer 330 wholly covers the polymer bump 320. In fact, the conductive layer 330 of the present invention may partially cover the polymer bump 320, as described in the following paragraphs.

The embodiments in FIGS. 23˜28 are similar to the embodiments in FIGS. 16˜22. The difference lies in that the conductive layer 330 in FIGS. 23˜28 partially covers the polymer bump 320 or partially covers the polymer bumps 320 and 360.

In addition, the polymer bump 320 in the above embodiments may be a block structure or a strip structure.

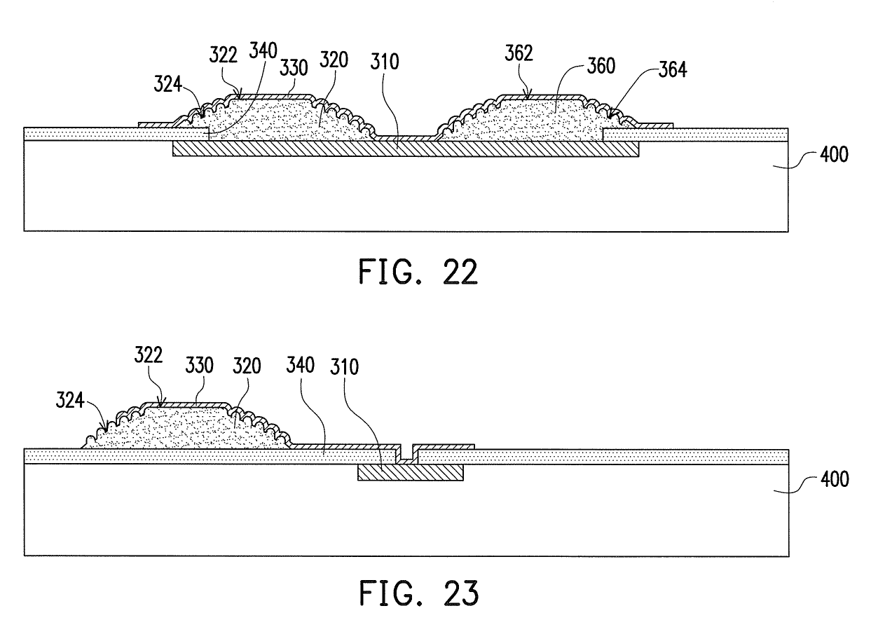

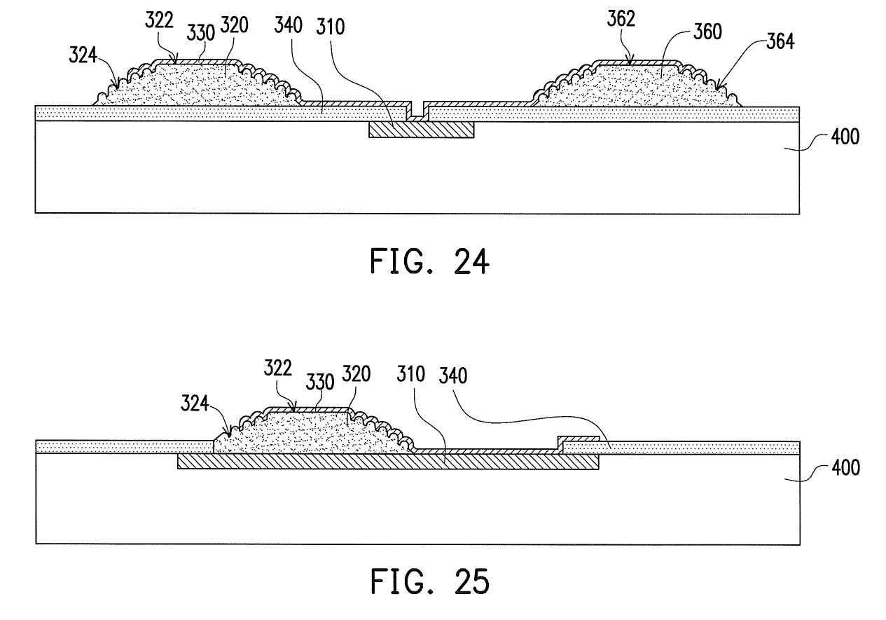

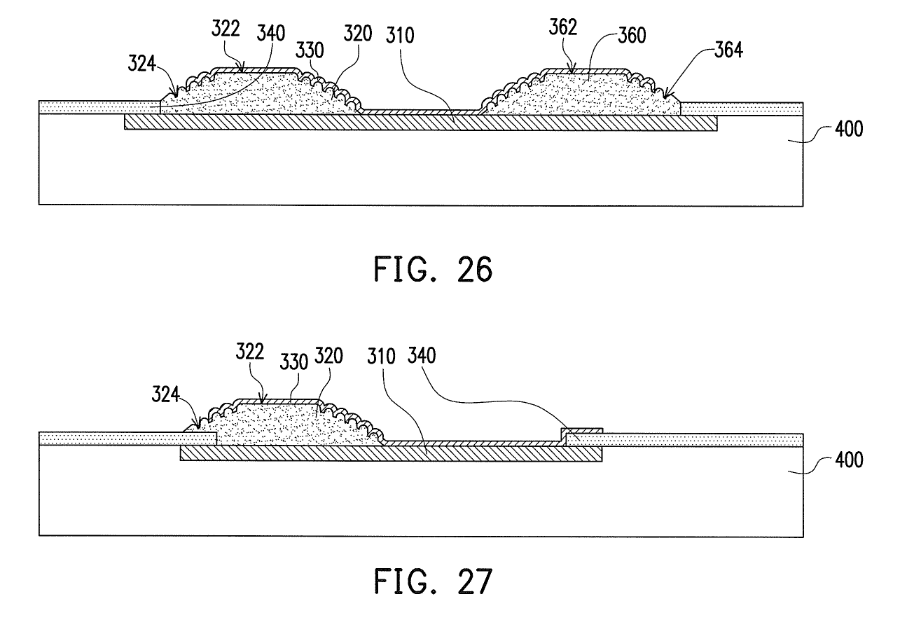

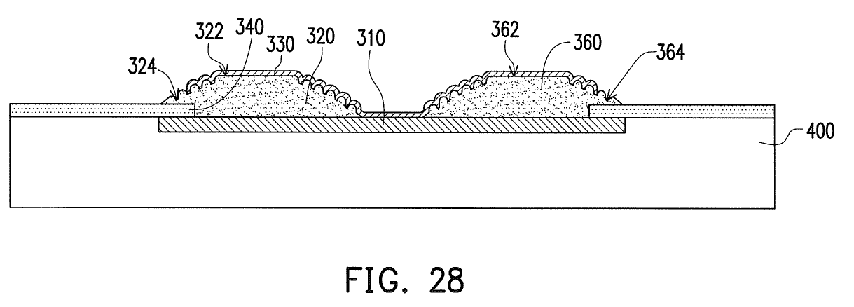

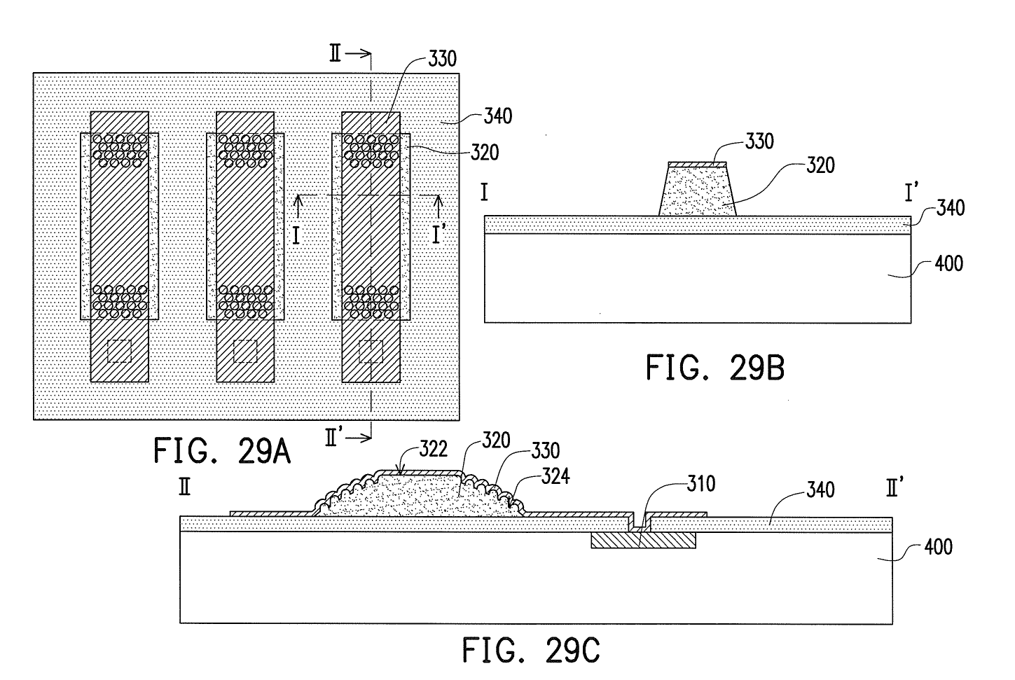

FIGS. 29A˜29C illustrate an embodiment in which the polymer bump 320 is a block structure. More particularly, the illustration of FIGS. 29A˜29C is based on the arrangement of the polymer bump 320 in FIG. 16. Although the present specification does not specifically illustrate the block structures of the polymer bumps 320 in the embodiments of FIGS. 17˜28, persons skilled in the art should have such an understanding based on the illustration of FIGS. 29A˜29C.

FIG. 29A is a schematic top view illustrating a contact structure according to an embodiment of the present invention. FIG. 29B is a schematic cross-sectional view illustrating the contact structure along the line I-I′ in FIG. 29A and FIG. 29C is a schematic cross-sectional view illustrating the contact structure along the line II-II′ in FIG. 29A. Referring to FIGS. 29A˜29C, the polymer bump 320 is a block structure, and the polymer bump 320 has the top flat surface 322 and curved surfaces 324 having concave-convex structures thereon at two sides of the top flat surface 322. Because the polymer bump 320 is a block structure, each polymer bump 320 is covered by one conductive layer 330 correspondingly.

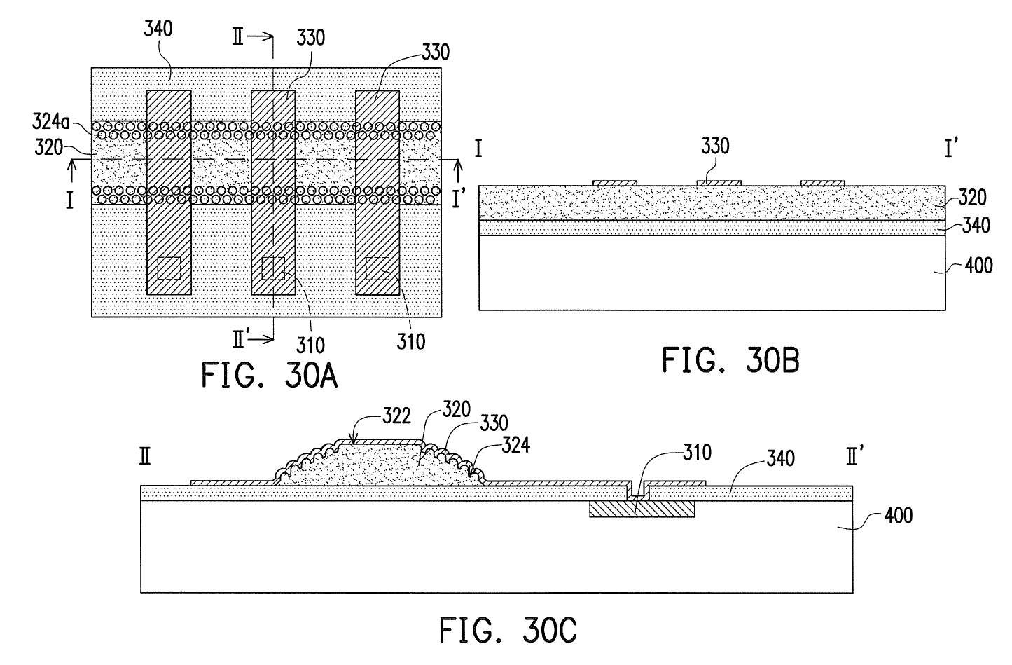

FIGS. 30A˜30C illustrate an embodiment in which the polymer bump 320 is a strip structure. More particularly, the illustration of FIGS. 30A˜30C is based on the arrangement of the polymer bump in FIG. 16. Although the present specification does not specifically illustrate the strip structures of the polymer bumps in the embodiments of FIGS. 17˜28, persons skilled in the art should have such an understanding based on the illustration of FIGS. 30A˜30C.

FIG. 30A is a schematic top view illustrating a contact structure according to another embodiment of the present invention. FIG. 30B is a schematic cross-sectional view illustrating the contact structure along the line I-I′ in FIG. 30A and FIG. 30C is a schematic cross-sectional view illustrating the contact structure along the line II-II′ in FIG. 30A. Referring to FIGS. 30A˜30C, when the polymer bump 320 is a strip structure, one polymer bump 320 is covered by a plurality of conductive layers 330, and each of the conductive layers 330 is electrically connected with one corresponding pad 310. Furthermore, in other embodiments, one polymer bump may be covered by a plurality of conductive layers electrically connected with one pad.

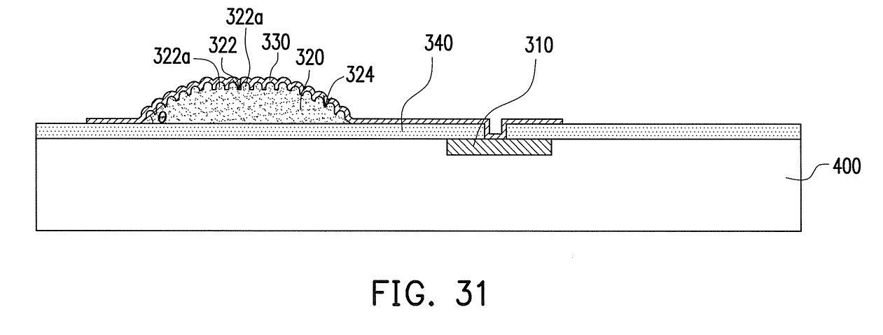

FIG. 31 is a schematic cross-sectional view of a contact structure according to another embodiment of the present invention. Referring to FIG. 31, a contact structure in FIG. 31 is similar to the contact structure 300 in FIG. 16. The difference lies in that the contact structure in FIG. 31 has the top flat surface 322 which further comprises a plurality of concave-convex structures 322a. In addition, the contact structures in FIGS. 17˜30 may be replaced by the contact structure in FIG. 31.

Further, the contact structures disclosed by FIGS. 1˜31 are respectively compressed with another substrate to form a connecting structure. The method for forming the connecting structure is described in detail as follows.

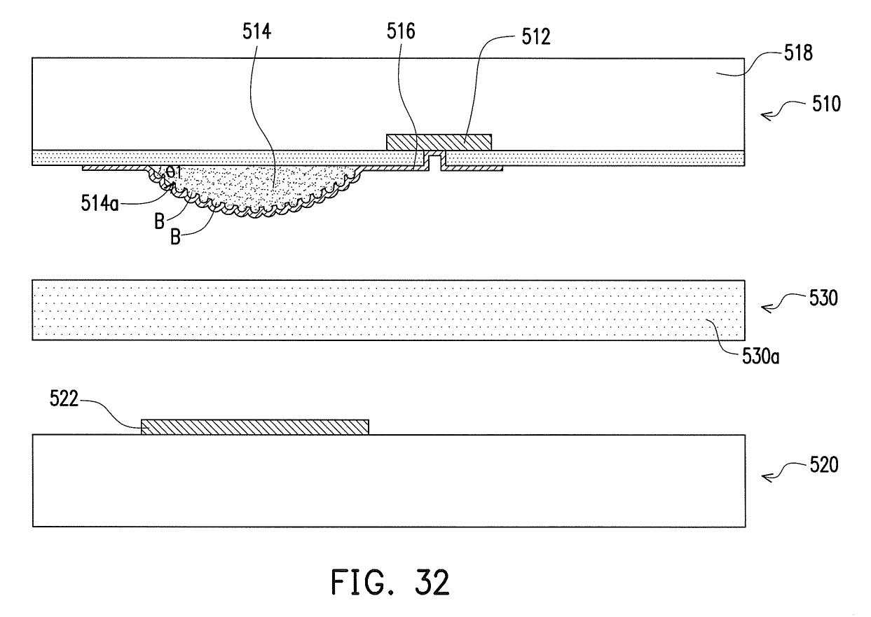

Referring to FIG. 32, a first substrate 510 and a second substrate 520 are provided first, wherein the first substrate 510 comprises at least a pad 512, at least a polymer bump 514, and at least a conductive layer 516. The polymer bump 514 is disposed to be corresponding to the pad 512, and the polymer bump 514 has a curved surface 514a which comprises a plurality of concave-convex structures B. It is noted that the contact structure on the first substrate 510 can be any of the contact structures in FIGS. 1˜15. The present invention is not limited to the structure as shown in FIG. 32. Moreover, in this embodiment, the first substrate 510 may further comprise a base layer 518 on which the pad 512, the polymer bump 514, and the conductive layer 516 are disposed. The first contact angle θ1 between the curved surface 514a of the polymer bump 514 and the base layer 518 is, for example, larger than 0 and smaller than or equal to 80 degrees. The conductive layer 516 covers the polymer bump 514 and is electrically connected with the pad 512. In addition, at least a conductive structure 522 is disposed on the second substrate 520.

Then, a bonding material 530 is disposed between the first substrate 510 and the second substrate 520. A side of the first substrate 510, at which the polymer bump 514 is disposed, and a side of the second substrate 520, at which the conductive structure 522 is disposed, both face to the bonding material 530. Herein, the bonding material 530 may be an ultraviolet curing bonding material, a thermal set bonding material, a thermoplastic bonding material, or a combination of the above. In other words, the bonding material 530 can be cured by an ultraviolet curing process, a heat curing process, a microwave curing process, an ultrasonic-wave curing process, or a combination of the above. Moreover, the bonding material 530 comprises a non-conductive adhesion paste, a non-conductive adhesion film, an anisotropic conductive paste, or an anisotropic conductive film. In this embodiment, the bonding material 530 further comprises a distribution of filling particles 530a. The aforesaid filling particles comprise electrically conductive or insulating particles.

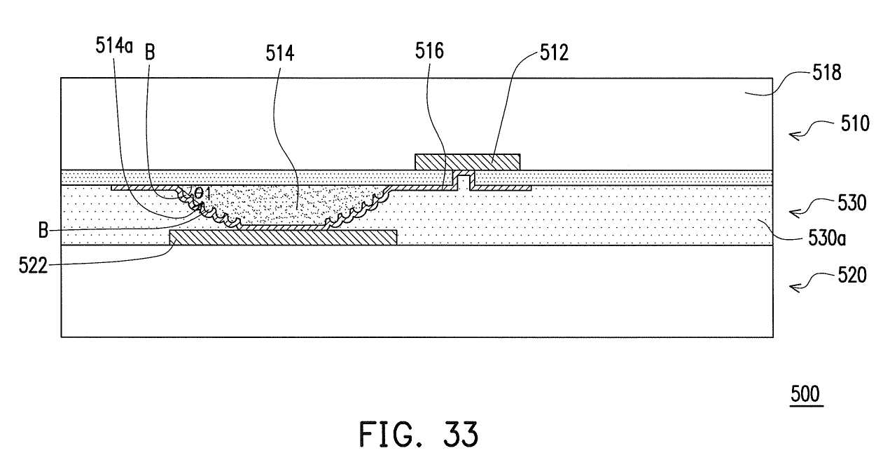

Next, referring to FIG. 33, the first substrate 510, the second substrate 520, and the bonding material 530 are compressed so that the polymer bump 514 and the conductive layer 516 can pass through the bonding material 530 to contact the conductive structure 522 and form a connecting structure 500.

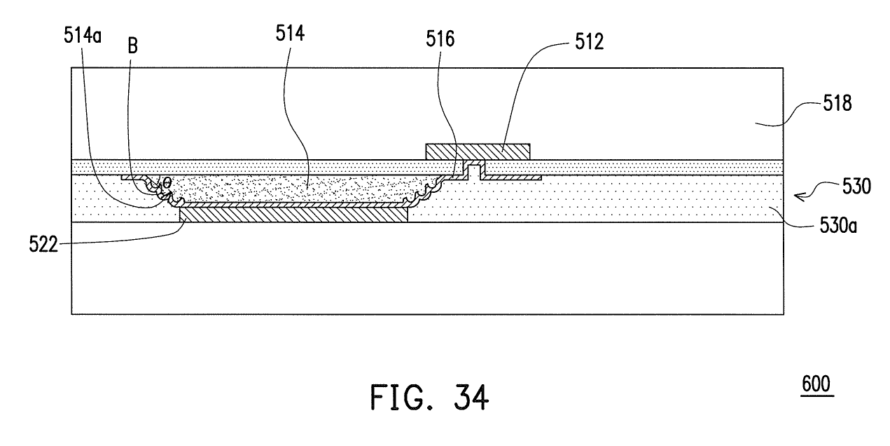

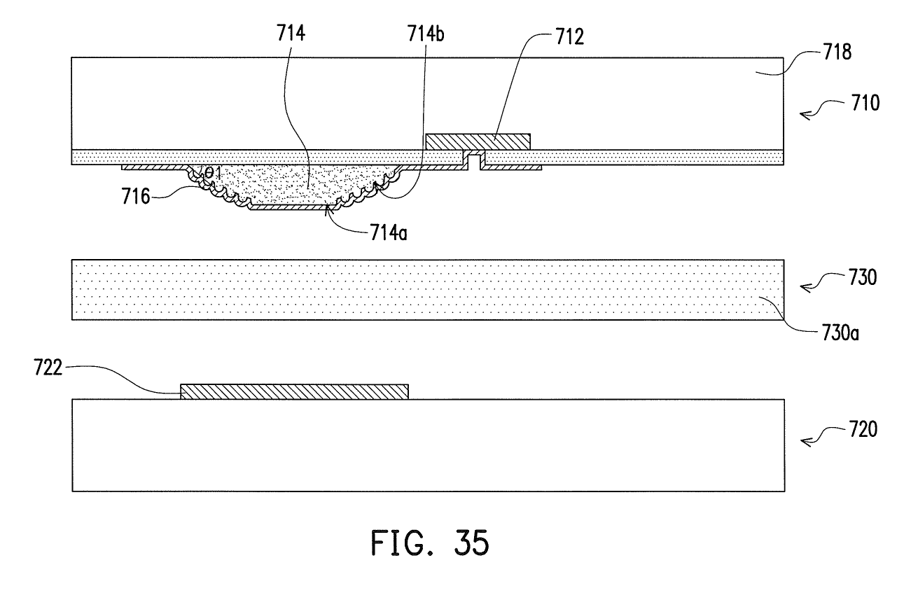

If larger pressure is applied during the compression, the polymer bump 514 may be slightly deformed and form the connecting structure 600 as shown in FIG. 34. The difference between the connecting structure 600 and the connecting structure 500 merely lies in that an area which a portion of the conductive layer 516 and the polymer bump 514 of the connecting structure 600 pass through the bonding material 530 to contact the conductive structure 522 is larger.

In view of the above, the polymer bump 514 of the connecting structures 500 and 600 in this embodiment has the curved surface 514a, which comprises the concave-convex structures B. The curved surface 514a of the polymer bump 514 does not cause stress concentration when the polymer bump 514 contacts the second substrate 520. Hence, the polymer bump 514 is capable of preventing stress concentration which easily results in the breaking of a metal layer on a conventional polymer bump when contacting another substrate. Furthermore, when the polymer bump 514 contacts the second substrate 520, the concave-convex structures B help the polymer bump 514 pass through the bonding material 530 to contact the conductive structure 522 of the second substrate 520.

A connecting structure and a method for forming the same according to another embodiment of the present invention are described as follows.

Referring to FIG. 35, a first substrate 710 and a second substrate 720 are provided first, wherein the first substrate 710 comprises at least a pad 712, at least a polymer bump 714, and at least a conductive layer 716. The polymer bump 714 is disposed to be corresponding to the pad 712. The polymer bump 714 has a top flat surface 714a and curved surfaces 714b having concave-convex structures thereon at two sides of the top flat surface 714a. Moreover, in this embodiment, the first substrate 710 may further comprise a base layer 718 on which the pad 712, the polymer bump 714, and the conductive layer 716 are disposed. In this embodiment, the curved surfaces 714b having concave-convex structures thereon protrude in a direction away from the substrate 718, and the first contact angle θ1 between the curved surfaces 714b having concave-convex structures thereon and the base layer 718 is, for example, larger than 0 and smaller than or equal to 80 degrees. The conductive layer 716 covers the polymer bump 714 and is electrically connected with the pad 712. In addition, at least a conductive structure 722 is disposed on the second substrate 720.

Then, a bonding material 730 is disposed between the first substrate 710 and the second substrate 720. A side of the first substrate 710, at which the polymer bump 714 is disposed, and a side of the second substrate 720, at which the conductive structure 722 is disposed, both face to the bonding material 730. Herein, the bonding material 730 may be an ultraviolet curing bonding material, a thermal set bonding material, a thermoplastic bonding material, or a combination of the above. In other words, the bonding material 730 can be cured by an ultraviolet curing process, a heat curing process, a microwave curing process, an ultrasonic-wave curing process, or a combination of the above. Moreover, the bonding material 730 comprises a non-conductive adhesion paste, a non-conductive adhesion film, an anisotropic conductive paste, or an anisotropic conductive film. In this embodiment, the bonding material 730 further comprises a distribution of filling particles 730a. The aforesaid filling particles comprise electrically conductive or insulating particles.

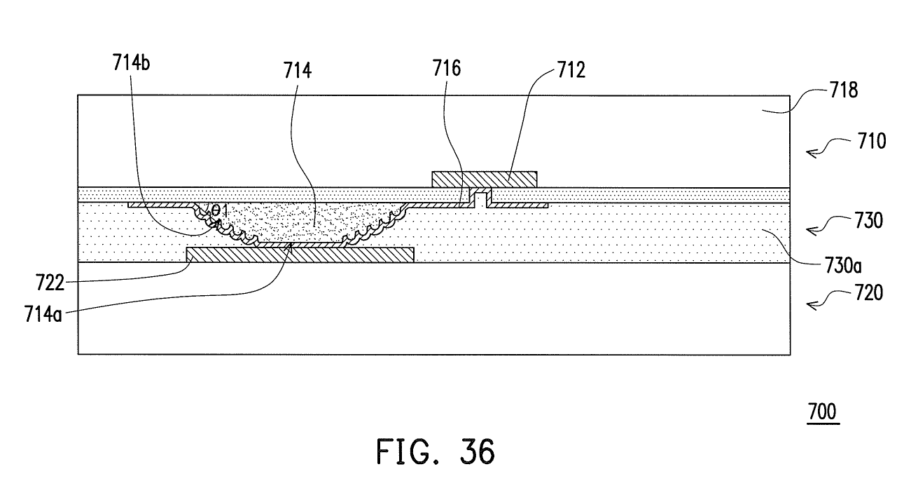

Next, referring to FIG. 36, the first substrate 710, the second substrate 720, and the bonding material 730 are compressed so that the polymer bump 714 and the conductive layer 716 can pass through the bonding material 730 to contact the conductive structure 722.

The difference between the connecting structure 700 and the connecting structure 500 in the aforesaid embodiment lies in that the polymer bump 714 in this embodiment further comprises the top flat surface 714a and the curved concave-convex surfaces 714b at two sides of the top flat surface 714a. As a consequence, an area, which the polymer bump 714 of the connecting structure 700 contacts the conductive structure 722 through the top flat surface 714a and the conductive layer 716, is larger than an area, which the polymer bump 514 of the connecting structure 500 contacts the conductive structure 522.

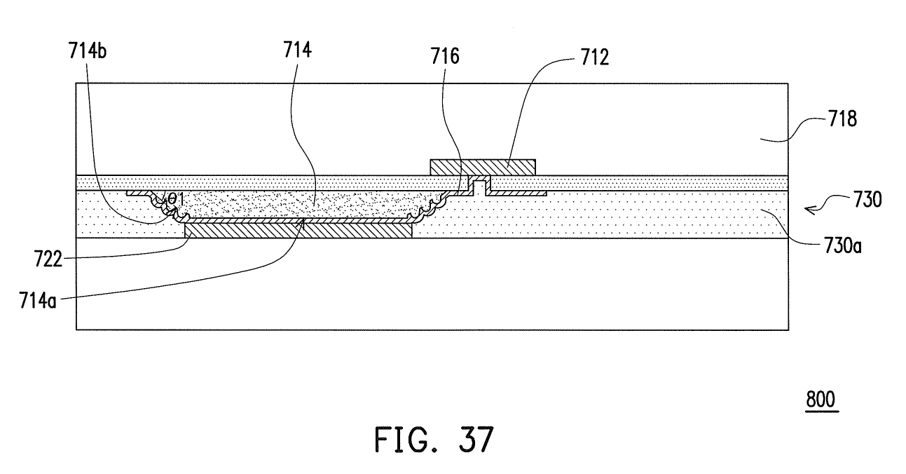

In addition, if larger pressure is applied during the compression, the polymer bump 714 may be slightly deformed and form the connecting structure 800 as shown in FIG. 37. The difference between the connecting structure 800 and the connecting structure 700 merely lies in that an area which a portion of the conductive layer 716 and the polymer bump 714 of the connecting structure 800 pass through the bonding material 730 to contact the conductive structure 722 is larger.

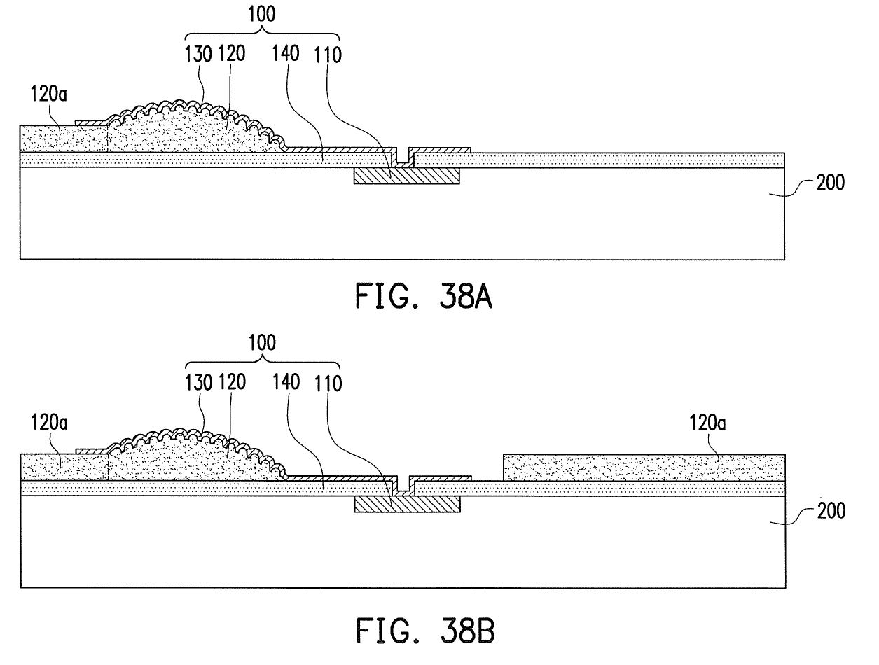

FIGS. 38A and 38B are schematic cross-sectional views of a contact structure according to another embodiment of the present invention. Referring to FIG. 38A, in addition to the aforesaid variations, a contact structure of the present invention may further comprise a polymer passivation layer 120a. The polymer passivation layer 120a may be defined when a polymer bump 120 is formed. In the embodiment as shown in FIG. 38A, the polymer passivation layer 120a is connected with the polymer bump 120 and covers a portion of a substrate 200. In another embodiment as shown in FIG. 38B, the polymer passivation layer 120a is connected with the polymer bump 120 and covers a large portion of the substrate 200. Particularly, the thickness of the polymer passivation layer 120a is smaller than the thickness of the polymer bump 120. The advantages of forming the polymer passivation layer 120a lie in that the structural strength of the polymer bump 120 can be enhanced to prevent the polymer bump 120 from breaking or peeling off the substrate 200, and the device can be protected.

It is noted that FIGS. 38A and 38B illustrate the position and property of the polymer passivation layer 120a based on the contact structure shown in FIG. 1. However, the polymer passivation layer 120a may also be disposed in the contact structures of other embodiments (such as FIGS. 2˜37) per requirements.

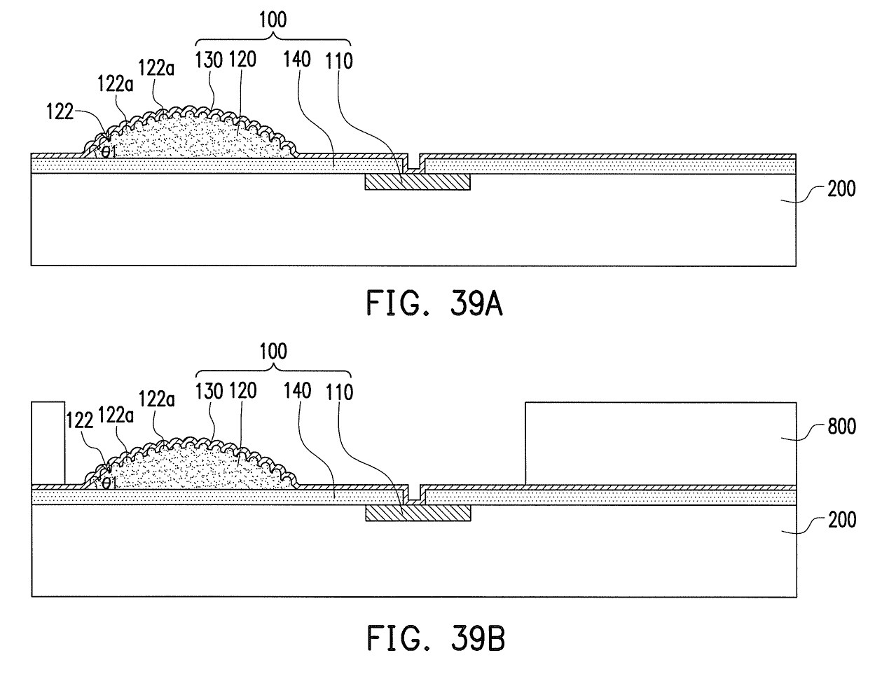

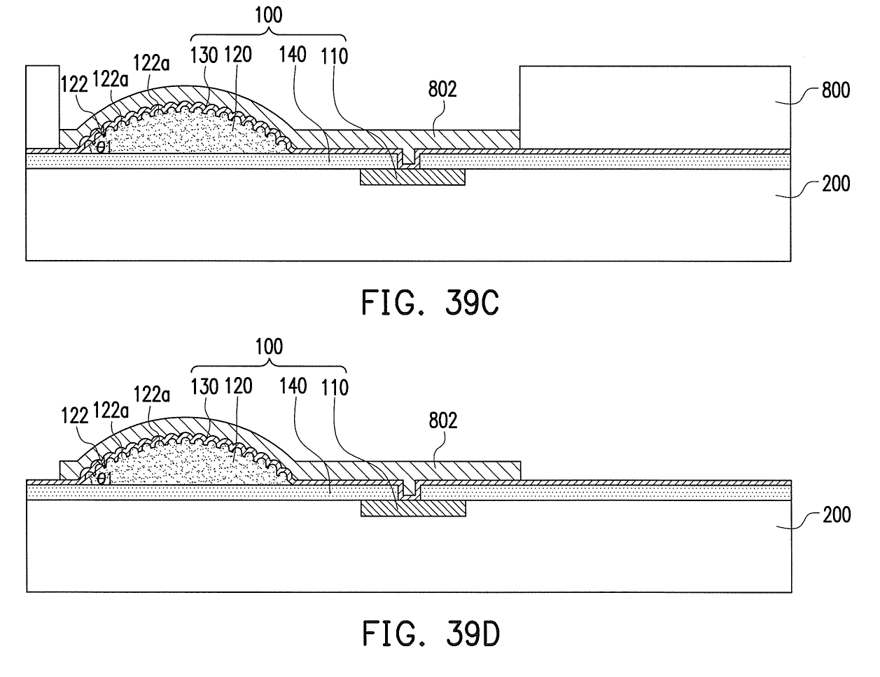

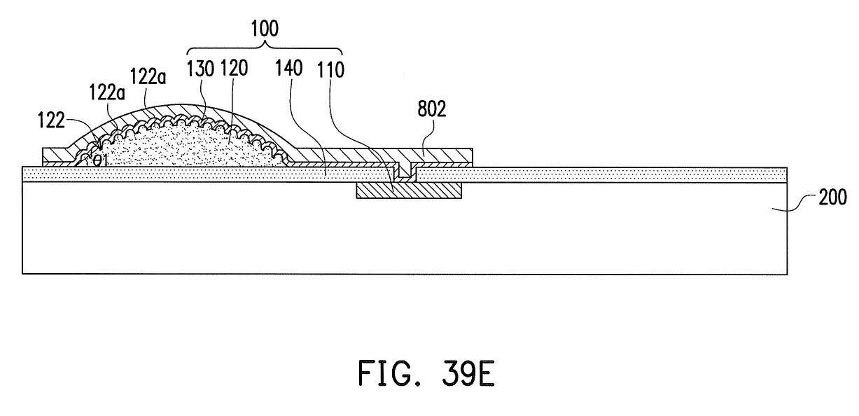

FIGS. 39A˜39E are schematic cross-sectional views illustrating a method for forming a contact structure according to an embodiment of the present invention. Referring to FIG. 39A, the conductive layer 130 is formed on the substrate 200 after the pad 110 and the polymer bump 120 are formed on the substrate 200. The conductive layer 130 covers the polymer bump 120 and contacts the pad 110. Next, as shown in FIG. 39B, a photoresist layer 800 is formed on the substrate 200, and the photoresist layer 800 exposes the conductive layer 130 on the polymer bump 120 and the pad 110. Then, referring to FIG. 39C, an electroplating process is performed to form a conductive layer 802 on the surface of the conductive layer 130 exposed by the photoresist layer 800. Particularly, because the conductive layer 802 is formed by the electroplating process, the thickness thereof can be easily increased.

Thereafter, the photoresist layer 800 is removed, as shown in FIG. 39D. Then, referring to FIG. 39E, a removing process is performed to completely remove the thin conductive layer 130 which is not covered by the thick conductive layer 802. In the meantime, a portion of the thickness of the conductive layer 802 is also removed.

Because the conductive layer 802 in this embodiment is formed by the electroplating process, the thickness of the remaining conductive layers 802 and 130 in FIG. 39E is thicker than that of a conductive layer formed by a deposition process. Consequently, the electrical conductivity of the contact structure is enhanced.

To conclude, the polymer bump of the contact structure and the connecting structure according to the present invention has a curved surface, which comprises a plurality of concave-convex structures. The curved surface of the polymer bump does not cause stress concentration when the polymer bump contacts the second substrate. Hence, the polymer bump is capable of preventing stress concentration which easily results in the breaking of a metal layer on a conventional polymer bump when contacting another substrate.

Furthermore, when the polymer bump contacts the second substrate, the concave-convex structures help the polymer bump pass through the bonding material to contact the conductive structure of the second substrate. In addition, the polymer bump of the contact structure and the connecting structure according to the present invention may comprise a top flat surface and curved concave-convex surfaces at two sides of the top flat surface. The polymer bump comprising the top flat surface has a larger contact area with the conductive structure of the second substrate.

Although the present invention has been disclosed by the above embodiments, they are not intended to limit the present invention. Persons of ordinary knowledge in the art may make some modifications and alterations without departing from the scope and spirit of the present invention. Therefore, the protection range sought by the present invention falls within the appended claims.

What is claimed is:

1. A contact structure disposed on a substrate, comprising:
at least a pad disposed on the substrate;
at least a polymer bump disposed on the substrate, wherein the polymer bump has a curved surface comprising a plurality of concave-convex structures; and
at least a conductive layer covering the polymer bump and electrically connected with the pad.

2. The contact structure as claimed in claim 1, wherein the conductive layer wholly or partially covers the polymer bump.

3. The contact structure as claimed in claim 1, further comprising a passivation layer disposed on the substrate and exposing the pad.

4. The contact structure as claimed in claim 1, wherein the polymer bump is disposed on the pad or on the substrate, or simultaneously traverses the pad and the substrate.

5. The contact structure as claimed in claim 1, wherein the at least one conductive layer cover(s) the same polymer bump and electrically connect(s) the at least one pad correspondingly.

6. The contact structure as claimed in claim 1, wherein the at least one conductive layer cover(s) the same polymer bump and electrically connect(s) the same pad.

7. The contact structure as claimed in claim 1, wherein the conductive layer on the polymer bump electrically connects the at least one pad.

8. The contact structure as claimed in claim 1, wherein the at least one conductive layer on the at least one polymer bump electrically connect(s) the same pad.

9. The contact structure as claimed in claim 1, further comprising a polymer passivation layer disposed on the substrate and at least exposing the polymer bump and the pad.

10. A contact structure disposed on a substrate, comprising:
at least a pad disposed on the substrate;
at least a polymer bump disposed on the substrate, wherein the polymer bump has a top flat surface and curved surfaces having concave-convex structures thereon at two sides of the top flat surface; and
at least a conductive layer covering the polymer bump and electrically connected with the pad.

11. The contact structure as claimed in claim 10, wherein the top flat surface comprises a plurality of concave-convex structures or is a smooth structure.

12. The contact structure as claimed in claim 10, wherein the conductive layer wholly or partially covers the polymer bump.

13. The contact structure as claimed in claim 10, further comprising a passivation layer disposed on the substrate and exposing the pad.

14. The contact structure as claimed in claim 10, wherein the polymer bump is disposed on the pad or on the substrate, or simultaneously traverses the pad and the substrate.

15. The contact structure as claimed in claim 10, wherein the at least one conductive layer cover(s) the same polymer bump and electrically connect(s) the at least one pad correspondingly.

16. The contact structure as claimed in claim 10, wherein he at least one conductive layer cover(s) the same polymer bump and electrically connect(s) the same pad.

17. The contact structure as claimed in claim 10, wherein the conductive layer on the polymer bump electrically connects the at least one pad.

18. The contact structure as claimed in claim 10, wherein the at least one conductive layer on the at least one polymer bump electrically connect(s) the same pad.

19. The contact structure as claimed in claim 10, further comprising a polymer passivation layer disposed on the substrate and at least exposing the polymer bump and the pad.

20. A connecting structure, comprising:
a first substrate, comprising:
at least a pad;
at least a polymer bump disposed to be corresponding to the pad, wherein the polymer bump has a curved surface comprising a plurality of concave-convex structures; and
at least a conductive layer covering the polymer bump and electrically connected with the pad;
a second substrate comprising at least a conductive structure, wherein the conductive layer of the first substrate is electrically connected with the conductive structure; and
a bonding material disposed between the first substrate and the second substrate, wherein a portion of the conductive layer and the polymer bump pass through the bonding material to contact the conductive structure.

21. The connecting structure as claimed in claim 20, wherein the bonding material comprises a non-conductive adhesion paste, a non-conductive adhesion film, an anisotropic conductive paste, or an anisotropic conductive film.

22. The connecting structure as claimed in claim 20, wherein the bonding material comprises an ultraviolet curing bonding material, a thermal set bonding material, a thermoplastic bonding material, or a combination thereof.

23. The connecting structure as claimed in claim 20, wherein the bonding material further comprises a distribution of filling particles.

24. The connecting structure as claimed in claim 23, wherein the filling particles comprise electrically conductive or insulating particles.

25. A connecting structure, comprising:
a first substrate, comprising:
at least a pad;
at least a polymer bump disposed to be corresponding to the pad, wherein the polymer bump has a top flat surface and curved surfaces having concave-convex structures thereon at two sides of the top flat surface; and
at least a conductive layer covering the polymer bump and electrically connected with the pad;
a second substrate comprising at least a conductive structure, wherein the conductive layer of the first substrate is electrically connected with the conductive structure; and
a bonding material disposed between the first substrate and the second substrate, wherein a portion of the conductive layer and the polymer bump pass through the bonding material to contact the conductive structure.

26. The connecting structure as claimed in claim 25, wherein the top flat surface comprises a plurality of concave-convex structures or is a smooth structure.

27. The connecting structure as claimed in claim 25, wherein the bonding material comprises a non-conductive adhesion paste, a non-conductive adhesion film, an anisotropic conductive paste, or an anisotropic conductive film.

28. The connecting structure as claimed in claim 25, wherein the bonding material comprises an ultraviolet curing bonding material, a thermal set bonding material, a thermoplastic bonding material, or a combination thereof.

29. The connecting structure as claimed in claim 25, wherein the bonding material further comprises a distribution of filling particles.

30. The connecting structure as claimed in claim 29, wherein the filling particles comprise electrically conductive or insulating particles.
